(19) United States
(12) Patent Application Publication
(10) Pub. No.: US 2008/0012084 A1
(43) Pub. Date: Jan. 17, 2008

(54) Image sensor package and method of fabricating the same

(75) Inventors: Yong-Hwan Kwon, Suwon-si (KR); Un-Byoung Kang, Hwaseong-si (KR); Chung-Sun Lee, Gunpo-si (KR); Woon-Seong Kwon, Suwon-si (KR); Hyung-Sun Jang, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/826,124

(22) Filed: Jul. 12, 2007

(30) Foreign Application Priority Data
Jul. 14, 2006 (KR) 10-2006-0066527

(51) Int. Cl. H01L 31/0232

(52) U.S. Cl. 257/432; 438/65; 257/E31.127

(57) ABSTRACT

An image sensor package may include a transparent substrate, an image sensor chip having a sensing region disposed over the transparent substrate, a resin protection dam disposed between the image sensor chip and the transparent substrate inside a wiring pattern, the resin protection dam having an aperture formed to expose a sensing region of the image sensor chip and defining a cavity between the sensing region and the transparent substrate, a resin filled on the transparent substrate outside the resin protection dam, and a black matrix pattern disposed on each side of the transparent substrate and configured to block excess transmission of light.

### FOREIGN PRIORITY INFORMATION

A claim of priority is made under 35 U.S.C. §119 to Korean Patent Application 2006-66527 filed on Jul. 14, 2006, the entirety of which is hereby incorporated by reference.

### BACKGROUND

Example embodiments of the present invention may relate to semiconductor devices and methods of fabricating the same. More specifically, the example embodiments of the present invention may relate to an image sensor package and a method of fabricating the same.

Image sensors are semiconductor electronic components, which is used for converting optical information to an electric signal. The image sensors may be classified into two categories: (1) charge coupled device (CCD) image sensors and (2) complementary metal-oxide-semiconductor (CMOS) image sensors.

An image sensor package is configured to protect an image sensor and enable light to impinge on a photo receiving surface or an active surface thereof.

The image sensor package may include a housing and a window through which light impinges on the photo receiving surface or the active surface of the image sensor. The image sensor package may further include a housing with a lens support, configured to support a lens, and an aperture into which the lens support is inserted.

FIGS. 1A and 1B are cross-sectional views illustrating conventional image sensors.

Referring to FIG. 1A, an image sensor chip 18 with a sensing region 18s is bonded directly to a transparent window 10. The transparent window 10 has a wiring pattern 12 connected to an external circuit (not shown). The wiring pattern 12 is electrically connected to the image sensor chip 18 by means of a bump 22 and electrically connected to the external circuit by a solder ball 13. A cavity 19 is provided between the sensing region 18s and the transparent window 10.

Referring to FIG. 1B, an image sensor chip 18 with a sensing region 18s is bonded to a housing-type substrate 20. The housing type substrate 20 has a wiring pattern 12 connected to an external circuit (not shown). The wiring pattern 12 is electrically connected to the image sensor chip 18 by means of a bump 22. The wiring pattern 12 may include a medium such as a solder ball (not shown) for connection to the external circuit. A transparent window 10 is bonded to the housing-type substrate 20. Thus, a cavity 19 is provided between the sensing region 18s and the transparent window 10.

The conventional image sensor package configurations illustrated in FIGS. 1A and 1B are achieved by bonding an image sensor chip to a window or a substrate. In general, a bonding process includes a thermal compression process. Therefore, a thin image sensor chip applied to an image sensor module used in small-sized devices may break/crack during the bonding process. This may hinder being able to decrease the thickness of the image sensor chip. Also, in the conventional image senor packages that light may be transmitted from sides of a transparent window, which could degrade sensitivity of the image senor chip.

### SUMMARY OF THE INVENTION

Example embodiments of the present invention may be directed to an image sensor package and a method of fabricating the same.

In an example embodiment, an image sensor package may include a transparent substrate, at least one wiring pattern disposed on the transparent substrate, and an image sensor chip electrically connected to the wiring pattern, the image sensor chip having a sensing region. The example embodiment may further include a resin protection dam disposed between the image sensor chip and the transparent substrate, the resin protection dam having an aperture formed to expose the sensing region of the image sensor chip and define a cavity between the sensing region and the transparent substrate, and a resin filled on the transparent substrate outside the resin protection dam.

In another example embodiment, the image sensor package may include a black matrix pattern disposed on each side of the transparent substrate and configured to block excess transmission of light.

In an example embodiment, a method of fabricating an image sensor package may include forming a plurality of wiring patterns on a transparent substrate, forming a plurality of resin protection dams on the transparent substrate in association with the plurality of wiring patterns, each resin protection dam having an aperture defining a cavity, electrically connecting a plurality of image sensor chips to the plurality of wiring patterns, each image sensor chip having a sensing region, each image sensor chip being associated with one of the plurality of resin protection dams such that the sensing region of the image sensor chip is disposed in the cavity of the associated resin protection dam, performing a filling process with a resin to cover the transparent substrate including the plurality of image sensor chips. Resin-free cavity is formed between the sensing region of the image sensor chip and the transparent substrate.

### BRIEF DESCRIPTION OF THE DRAWINGS

FIGS. 1A and 1B are cross-sectional views illustrating conventional image sensor packages.

FIG. 2A is a perspective view illustrating an image sensor package according to an example embodiment of the present invention.

FIG. 2B is a cross-sectional view taken along a line IIB-IIB′ of FIG. 2A.

FIGS. 3A through 3L are cross-sectional views illustrating a method of fabricating an image sensor package according to an example embodiment of the present invention.

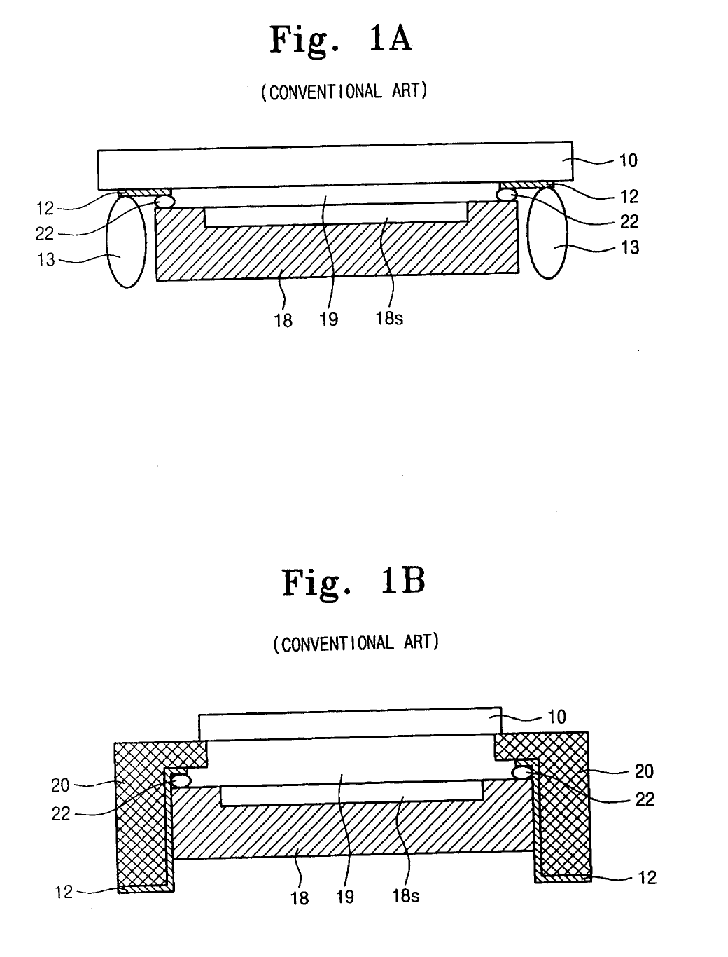

### DETAILED DESCRIPTION

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

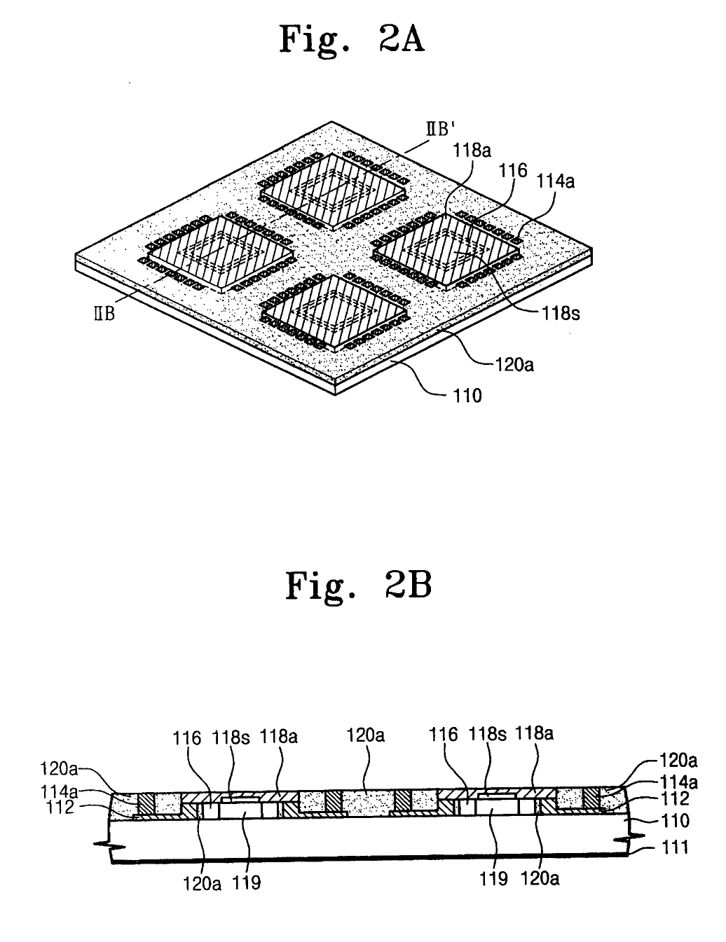

FIG. 2A is a perspective view illustrating an image sensor package according to an example embodiment of the present invention, and FIG. 2B is a cross-sectional view taken along a line IIB-IIB′ of FIG. 2A.

Referring to FIGS. 2A and 2B, a plurality of wiring patterns 112 may be arranged on a transparent substrate 110 to form a desired configuration. A plurality of post bumps 114a may be provided on the plurality of wiring patterns 112 to electrically connect the plurality of wiring patterns 112 to an external circuit (not shown). An image sensor chip 118a may be provided and electrically connected to each of the plurality of wiring patterns 112. A resin protection dam 116 with an aperture (space) formed to expose a sensing region 118s of the image sensor chip 118a may be provided between the transparent substrate 110 and the image sensor chip 118a. The resin protection dam 116 may be a resin blocking wall. A resin 120 may be provided to fill a space on the transparent substrate 110 external to the resin protection dam 116. Thus, a cavity 119 between the sensing region 118s of the image sensor chip 118a and the transparent substrate 110 may be provided. On an opposite face of the substrate 110, an infrared filter (IR filter) 111 may be formed.

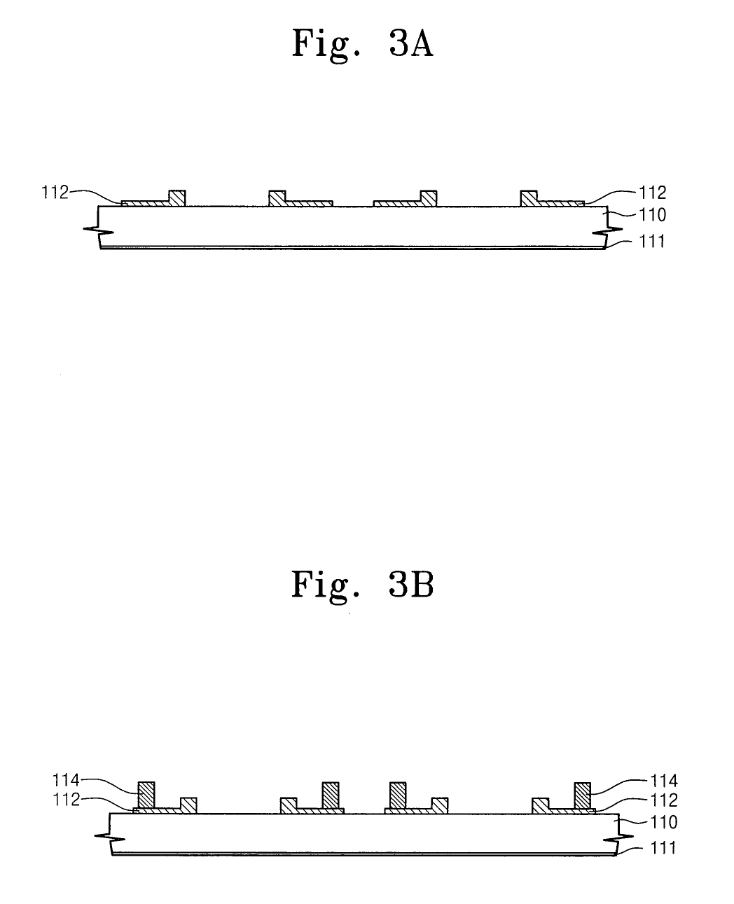

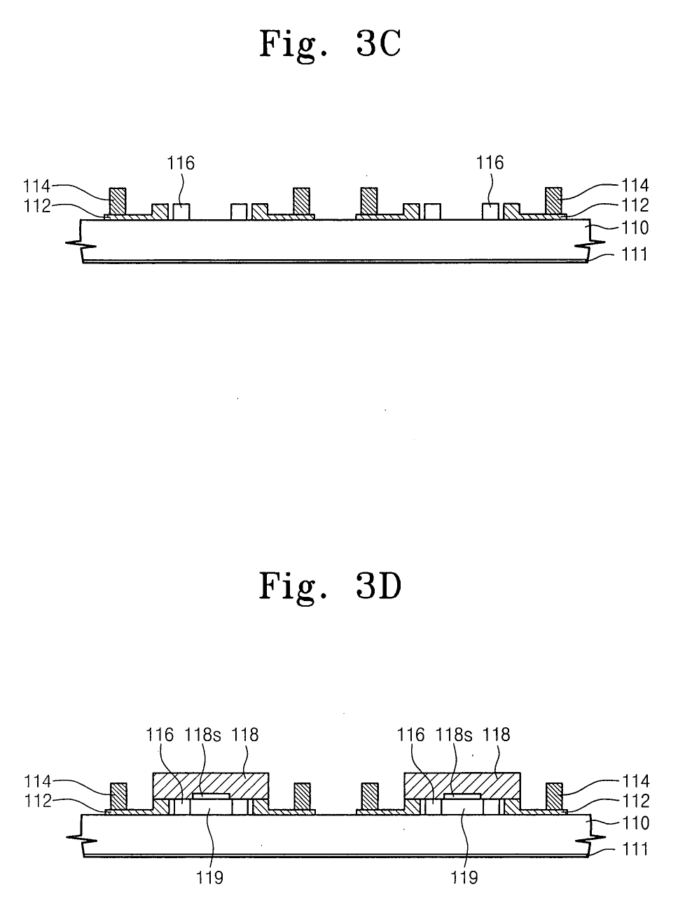

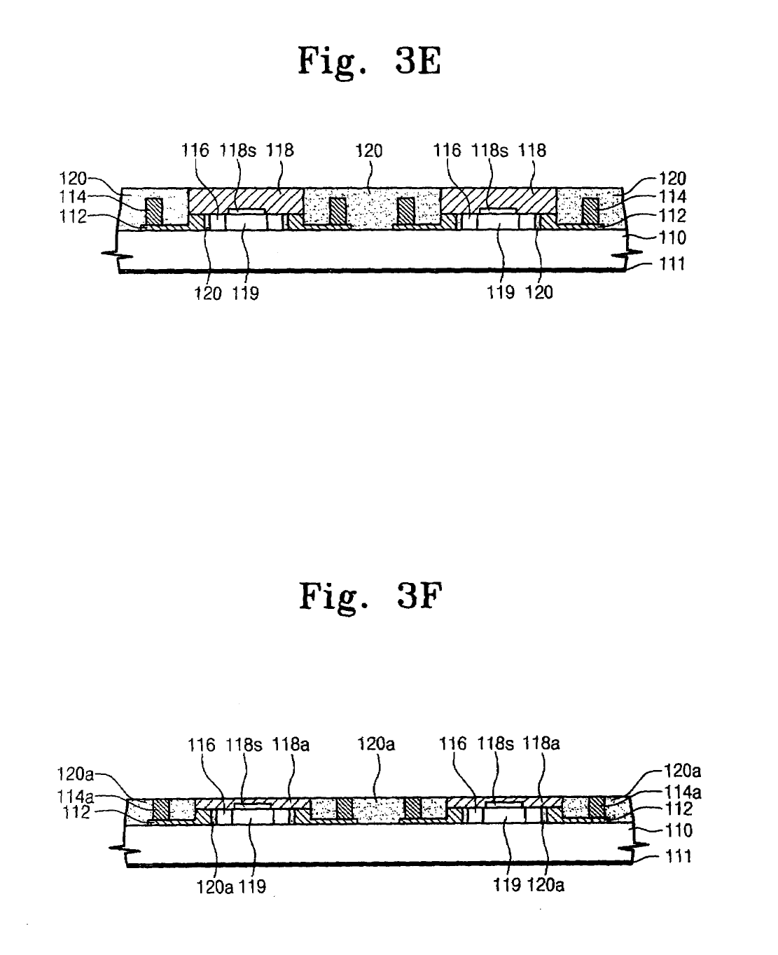

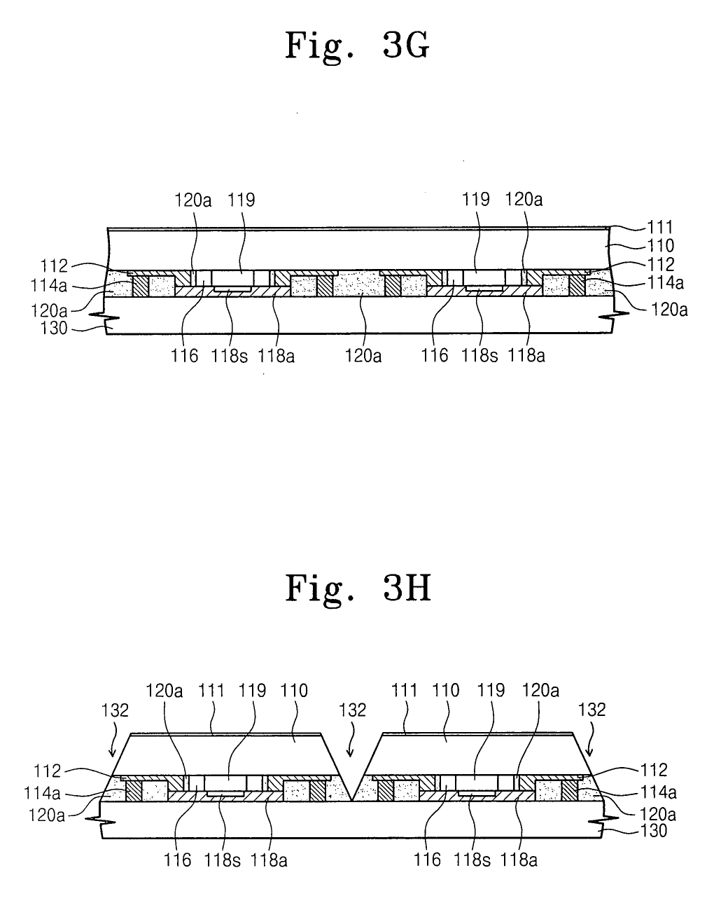

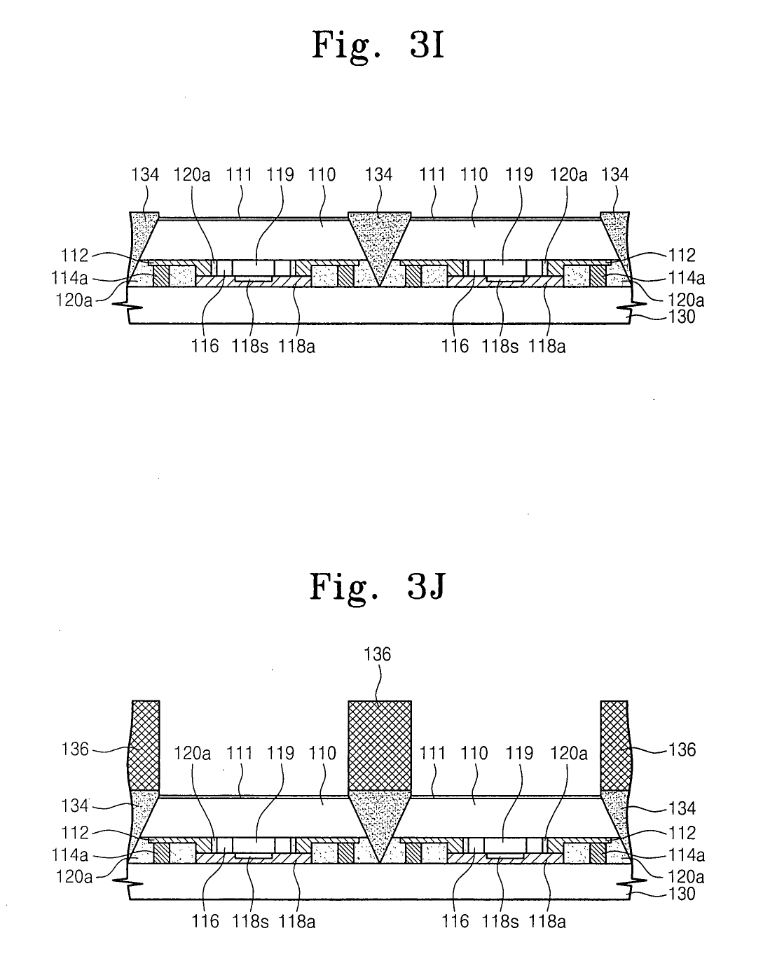

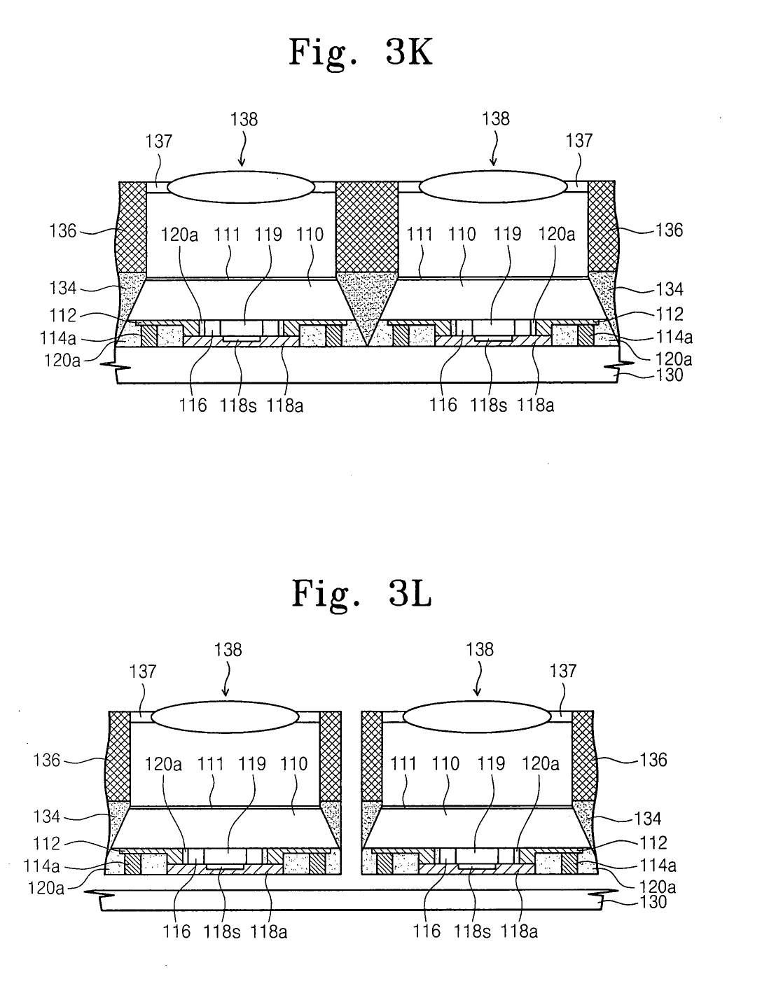

FIGS. 3A through 3L are cross-sectional views, taken along a line IIB-IIB′ of FIG. 2A, illustrating a method of fabricating an image sensor package according to an example embodiment of the present invention.

Referring to FIG. 3A, a seed metal film (not shown) may be formed to cover the entire surface of the transparent substrate 110. The transparent substrate 110 may be a glass substrate with excellent light transmission properties. The transparent substrate 110 may be made of soda-lime glass or borosilicate glass. An infrared filter 111 may be formed on a surface of the transparent substrate 110, opposite the seed metal film to block light (infrared region) impinging on an image sensor.

The seed metal film may serve to facilitate a wiring pattern, and may also function as an electrode in an electroplating process to form the wiring pattern and a post bump in subsequent processes. The seed metal film may be formed by a physical vapor deposition (PVD) process. The seed metal film may be a multi-layer film including first, second, and third layers. The first layer may include titanium (Ti), titanium tungsten (TW), chrome (Cr), and/or titanium nitride (TiN). The second layer may include copper (Cu), nickel (Ni), nickel vanadium (NiV), gold (Au), and/or silver (Ag). The third layer may include gold (Au), silver (Ag), and/or platinum (Pt). In example embodiments, the seed metal film may only include two layer films including the first layer and the second layer. In other example embodiments, the seed metal film may be more than three layers.

A photoresist pattern (not shown) for the wiring pattern with a desired-shaped aperture to partially expose a surface of the seed metal film may be formed on the seed metal layer. The seed metal film may then be etched to form a plurality of wiring patterns 112 having a desired configuration. After forming a plurality of wiring patterns 112 in the apertures, the photoresist pattern may be removed. The desired configuration of the wiring patterns 112 may be identical to that of bonding pads (not shown) in an image sensor chip. The plurality of wiring patterns 112 may act as a connection between the image sensor chip and an external circuit (not shown).

The plurality of wiring patterns 112 may be formed to a thickness ranging from about 1 to 10 micrometers. The plurality of wiring patterns 112 may include gold (Au), silver (Ag), nickel (Ni), and/or copper (Cu). The plurality of wiring patterns 112 may have a protrusion for connecting to the bonding pads of the image sensor chip in a subsequent process. Accordingly, additional steps of a photoresist pattern process and an electroplating process may be added to form the protrusion. In the case where the bonding pads of an image sensor chip includes a protrusive bump, the plurality of wiring patterns 112 may have a flat shape without any protrusions. Protrusions on the wiring pattern 112 and bumps on the image sensor chip may be provided to achieve better bonding therebetween.

Referring to FIG. 3B, a photoresist pattern (not shown) with apertures formed to partially expose surfaces of the plurality of wiring patterns 112 may be formed on the plurality of wiring patterns 112. Post bumps 114 are then formed in the apertures, and the photoresist pattern may be removed. The post bumps 114 may also act as a connection between the plurality of wiring patterns 112 and an external circuit.

The post bumps 114 may be formed to a thickness ranging from about 20 to 200 micrometers by an electroplating process. The post bumps 114 may include gold (Au), silver (Ag), nickel (Ni), tin-alloy (Sn-alloy), and/or combinations thereof, for example, copper-nickel-lead (Cu—Ni—Pb), copper-nickel-gold (Cu—Ni—Au), copper-nickel (Cu—Ni), nickel-gold (Ni—Au), nickel-silver (Ni—Ag), etc.

Referring to FIG. 3C, residual seed metal film on the exposed transparent substrate 110 adjacent to the plurality of wiring patterns 112 may be removed. The residual seed metal film may be removed by a wet etch process. Resin protection dams 116, each having an aperture formed to define a sensing region 118s of the image sensor chip may be formed on the transparent substrate 110 inside the plurality of wiring patterns 112. The resin protection dams 116 may serve to prevent resin from filling the space between sensing regions of each the image sensor chips and the transparent substrate 110 during a resin filling process described below.

The resin protection dams 116 may be formed to a thickness ranging from about 10 to 30 micrometers by means of a screen printing process or a metal plating process. The resin protection dams 116 may include benzocyclobuten (BCB), polyimide, epoxy, and/or metal material such as copper or nickel.

Referring to FIG. 3D, image sensor chips 118 may be connected (e.g., bonded) to the plurality of wiring patterns 112 such that the resin protection dams 116 may adhere closely to the image sensor chips 118. The image sensor chips 118 may have a thickness ranging from about 600 to 750 micrometers.

Bonding the image sensor chips 118 to the plurality of wiring patterns 112 may include a thermocompression process or a thermosonic compression process. The sensing region 118s may be defined between the image sensor chips 118 and the transparent substrate 110. Cavities 119 surrounded by the resin protection dams 116 may be formed between the sensing regions 118s of the image sensor chips 118 and the transparent substrate 110. As previously described with reference to FIG. 3A, wiring patterns 112 may include a protrusion connected to the bonding pads of the image sensor chip 118. Or, if the bonding pad of the image sensor chips 118 includes a protrusive bump, the wiring patterns 112 may have a flat shape without the protrusion. A protrusion of the wiring pattern 112 and a bump of an image sensor chip 118 are provided to achieve easy bonding therebetween.

Referring to FIG. 3E, a filling process may be performed with resin 120 to cover the entire surface of the transparent substrate 110 including the image sensor chips 118. The resin 120 may function as a buffer during a subsequent polishing process to reduce the thickness of the image sensor chips 118.

The filling process with the resin 120 may be performed by a dispensing process. The resin 120 may include an epoxy group. The resin 120 may fill all spaces on the transparent substrate 110 external to the resin protection dams 116. Accordingly, the resin protection dams 116 may protect the cavities 119 from penetration of the resin 120, and prevent/reduce the degradation of sensitivity characteristics of the image sensor chips 118. For example, if the transparent resin 120 migrates between the sensing region 118s and the transparent substrate 110 during the filing process, light loss may be 5-10 percent higher.

Referring to FIG. 3F, after the filling process with the resin 120, a polishing process may be performed to polish the resin 120 and the image sensor chips 118. The polishing process may include a back lap process or a chemical mechanical polishing (CMP) process. The polishing process may decrease the thickness of the image sensor chips 118 and expose the post bumps 114. As a result of the polishing process, thin image sensor chips 118a, post bumps 114a, and a thin resin 120a may be formed. Each of the thin image sensor chips 118a may have a thickness ranging from about 20 to 200 micrometers.

Referring to FIG. 3G, a holder 130 may be connected (e.g., bonded) to the polished surface. For example, the holder 130 may be connected to the exposed surface of the thin image sensor chips 118a. The holder 130 may serve to hold a formation obtained after the polishing process.

Generally, the holder 130 may include inflexible material. The formation obtained after the polishing process may be connected to the holder 130 by a tape. Both surfaces of the tape may be adhesive for use during a wafer cutting process or a back lap process.

Referring to FIGS. 3H and 3I, portions of the transparent substrate 110 and the resin 120 between two adjacent thin image sensor chips 118a may be removed to form a groove 132. A saw blade may be used to form the groove 132 such that the groove 132 has a V-shaped cross-section. Further, the transparent substrate 110 of each image sensor package may have a tapered edge.

A black matrix pattern 134 may be formed in the groove 132 to prevent unnecessary transmission of light from impinging on the thin image sensor chip 118a. Forming the black matrix pattern 134 may include a dispensing process or a screen printing process. The black matrix pattern 134 may include a black epoxy group, and the black matrix pattern 134 may protrude above the surface of the transparent substrate 110.

Referring to FIGS. 3J and 3K, lens supports 136 may be formed on the black matrix pattern 134. The formation of the lens supports 136 may be accomplished by compressing a mash-type plastic. Lenses 138 may be mounted between the lens supports 136. The lenses 138 may also be mounted between the lens supports 136 by a spacer 137.

Referring to FIG. 3L, individual image sensor packages may be formed by cutting the lens support 136 and the black matrix pattern 134 between two adjacent thin image sensor chips 118a. The holder 130 may be removed from the image sensor packages to finish the fabrication of the individual and separate image sensor packages.

An image sensor package fabricated according to example embodiments of the present invention described above may reduce/prevent degradation of the sensing characteristic.

Sensing characteristic degradation of the image sensor may result from transmitted light impinging on sides of the image sensor. A transmission blocking pattern formed to surround edges of the image sensor may be provided to prevent the degradation. Further, a lens unit mounted on the transparent substrate formed without a housing simplifies the fabrication process.

Although example embodiments of the present invention have been described and in connection with the accompanying drawings, the example embodiments of the present invention are not limited thereto. It will be apparent to those skilled in the art that various substitutions, modifications and changes may be made without departing from the present invention.

What is claimed is:

1. An image sensor package comprising:
a transparent substrate;
at least one wiring pattern disposed on the transparent substrate;
an image sensor chip electrically connected to the wiring pattern, the image sensor chip having a sensing region;
a resin protection dam disposed between the image sensor chip and the transparent substrate, the resin protection dam having an aperture formed to expose the sensing region of the image sensor chip and define a cavity between the sensing region and the transparent substrate; and
a resin filled on the transparent substrate outside the resin protection dam.

2. The image sensor package of claim 1, wherein the resin protection dam includes one selected from the group consisting of benzocyclobuten (BCB), polyimide, epoxy, and metal material.

3. The image sensor package of claim 1, further comprising:
a black matrix pattern disposed on each side of the transparent substrate and configured to block excess transmission of light;
a lens support disposed on the black matrix pattern; and
a lens installed on the lens support.

4. The image sensor package of claim 3, wherein the black matrix pattern includes a black epoxy group.

5. The image sensor package of claim 1, further comprising:
a post bump disposed on the wiring pattern and configured to connect the wiring pattern to an external circuit.

6. The image sensor package of claim 1, wherein the wiring pattern includes a protrusion to electrically connect to the image sensor chip.

7. A method of fabricating an image sensor package, comprising:
forming a plurality of wiring patterns on a transparent substrate;
forming a plurality of resin protection dams on the transparent substrate in association with the plurality of wiring patterns, each resin protection dam having an aperture defining a cavity;
electrically connecting a plurality of image sensor chips to the plurality of wiring patterns, each image sensor chip having a sensing region, each image sensor chip being associated with one of the plurality of resin protection dams such that the sensing region of the image sensor chip is disposed in the cavity of the associated resin protection dam;
performing a filling process with a resin to cover the transparent substrate including the plurality of image sensor chips,
wherein resin-free cavity is formed between the sensing region of the image sensor chip and the transparent substrate.

8. The method of claim 7, further comprising:
forming a plurality of post bumps on the plurality of wiring patterns, the plurality of post bumps configured to connect the plurality of wiring patterns to an external circuit.

9. The method of claim 8, wherein the forming the post bumps comprises:
forming a post bump photoresist pattern, the post bump photoresist pattern having post bump apertures formed to partially expose a surface of the plurality of wiring patterns;
depositing the post bumps in the post bump apertures; and
removing the post bump photoresist pattern.

10. The method of claim 7, wherein the forming of the plurality of wiring patterns comprises:
forming a seed metal film on the transparent substrate;
forming a wiring pattern photoresist pattern on the seed metal film, the wiring pattern photoresist pattern having wiring pattern apertures to partially expose a surface of the seed metal film;
depositing the plurality of wiring patterns in the wiring pattern apertures; and
removing the wiring pattern photoresist pattern.

11. The method of claim 7, wherein the plurality of resin protection dams are formed by a screen printing process or a metal plating process.

12. The method of claim 11, wherein the plurality of resin protection dams includes one selected from the group consisting of benzocyclobuten (BCB), polyimide, epoxy, and metal material.

13. The method of claim 7, wherein the plurality of image sensor chips are electrically connected to the plurality of wiring patterns by a thermocompression process or a thermosonic compression process.

14. The method of claim 7, further comprising:
polishing the resin and the plurality of image sensor chips by a polishing process.

15. The method of claim 14, wherein the polishing process includes a back lap process or a chemical mechanical polishing (CMP) process.

16. The method of claim 14, further comprising:
connecting a holder to a surface polished by the polishing process;
selectively removing portions of the resin and the transparent substrate between the plurality of image sensor chips to form a groove;
forming a black matrix pattern on the groove;
forming lens supports on the black matrix pattern; and
providing lenses between the lens supports.

17. The method of claim 16, wherein the groove is formed to have a V-shaped cross-section.

18. The method of claim 16, wherein the black matrix pattern is formed by a dispensing process or a screen printing process.

19. The method of claim 18, wherein the black matrix pattern includes a black epoxy group.

20. The method of claim 16, further comprising:
cutting the black matrix pattern and the lens supports between the plurality of image sensor chips to form individual image sensor packages.
